(19) United States
(12) Patent Application Publication
(10) Pub. No.: US 2024/0186809 A1
(43) Pub. Date: Jun. 6, 2024

(54) FULL CHARGE CAPACITY ESTIMATION METHOD AND CONTROL DEVICE

(71) Applicant: TOYOTA JIDOSHA KABUSHIKI KAISHA, Toyota-shi (JP)

(72) Inventors: Mitsuru TATEISHI, Toyota-shi (JP); Hajime Hasegawa, Aichi-gun (JP); Shun Takeoka, Toyota-shi (JP); Shinya Takeshita, Toyota-shi (JP); Takashi Okada, Toyota-shi (JP); Chihiro Matsuda, Toyohashi-shi (JP); Tomoyuki Kawai, Kariya-shi (JP); Toshiya Arakawa, Kariya-shi (JP)

(73) Assignee: TOYOTA JIDOSHA KABUSHIKI KAISHA, Toyota-shi (JP)

(21) Appl. No.: 18/506,671

(22) Filed: Nov. 10, 2023

(30) Foreign Application Priority Data
Dec. 2, 2022 (JP) 2022-193547

(51) Int. Cl. H02J 7/00; G01R 31/367; G01R 31/378; G01R 31/3842; G01R 31/388; H01M 10/44; H01M 10/46

(52) U.S. Cl. CPC H02J 7/0049; G01R 31/367; G01R 31/378; G01R 31/3842; G01R 31/388; H01M 10/441; H01M 10/446; H01M 10/46

(57) ABSTRACT

A bipolar LFP battery includes a plurality of cells that are stacked together. A positive electrode active material layer of each of the cells includes lithium iron phosphate. A ΔQ calculation unit calculates an increase ΔQ of a charge amount, during charging of the cell of the bipolar LFP battery. The increase ΔQ is an increase in the charge amount of the cell when the voltage of the cell increases from a first voltage to a second voltage. A full charge capacity estimation unit uses a full charge capacity map to estimate the full charge capacity of the cell, using the increase ΔQ of the charge amount as a parameter.

This nonprovisional application is based on Japanese Patent Application No. 2022-193547 filed on Dec. 2, 2022 with the Japan Patent Office, the entire contents of which are hereby incorporated by reference.

### BACKGROUND

### Field

The present disclosure relates to a full charge capacity estimation method and a control device.

### Description of the Background Art

Japanese Patent Application Laid-Open No. 2021-58071 discloses a technique for setting a charge rate (SOC (State Of Charge)) of a battery to 100%. According to this technology, it is determined that constant-current constant-voltage charging (CCCV (Constant Current Constant Voltage) Charge) has been performed using the battery voltage after the battery (secondary battery) has been charged.

### SUMMARY

Bipolar batteries have been proposed to reduce internal resistance and improve output density. The bipolar battery includes a plurality of bipolar electrodes. Adjacent bipolar electrodes are stacked with a separator interposed therebetween. Each bipolar electrode includes a current collector, a positive electrode, and a negative electrode. The positive electrode is formed on one surface of the current collector. The negative electrode is formed on the other surface of the current collector. Each cell (single cell) of the bipolar battery includes a positive electrode, a separator, and a negative electrode. The basis weight of the cell (e.g., the density of the positive electrode and the density of the negative electrode) may vary due to variations during manufacturing. As a result, the capacity of each cell may vary.

A plurality of cells of a bipolar battery are stacked and electrically connected in series. In order to prevent overcharging of each cell, charging of the bipolar battery may end when a cell having a small full charge capacity is charged to a full charge state. As a result, the cell having a large full charge capacity is not fully charged. It is known that a lithium iron phosphate ion battery (LFP battery) has a flat region (voltage flat region) in a wide range in the OCV (Open Circuit Voltage)-SOC characteristic. The positive electrode active material of the LFP battery includes lithium iron phosphate. FIGS. 6A and 6B illustrate characteristics of the LFP battery. FIG. 6A shows the OCV-SOC characteristics of the LFP battery. This characteristic has a wide region (voltage flat region) in which the change in OCV due to the change in SOC is minute.

FIG. 6B shows a characteristic of each cell when two LFP cells (cells) different from each other in full charge capacity are charged to a full charge state. In FIG. 6B, the abscissa represents the amount of stored electricity [Ah], and the ordinate represents the voltage of the LFP battery (cell). Note that the charging method is CC (Content Current) charging or CCCV charging. In FIG. 6B, a dashed line indicates a characteristic of a cell having a full charge capacity of C1. The solid line indicates a characteristic of a cell having a full charge capacity of C2 (>C1). In order to prevent the cell of the bipolar battery from being overcharged, the charging may end when the cell having the full charge capacity of C1 becomes fully charged (when the charge amount reaches C1). Thus, the charging of the cell having the full charge capacity of C2 is also terminated. As a result, for the cell having the full charge capacity of C2, the range surrounded by the one-dot chain line becomes the unused area. The voltage (positive electrode potential) of the cell having the full charge capacity of C2 does not rise to the foreign substance dissolution potential indicated by the two-dot chain line. In particular, the LFP battery has a lower battery voltage than the ternary lithium ion battery. Therefore, the positive electrode potential of the cell having the full charge capacity of C2 often does not rise to the foreign substance dissolution potential. As a result, in the cell having the full charge capacity of C2, there is a concern that foreign substances are not dissolved and potential short circuit defects are caused. In order to solve the possibility of such a potential short circuit failure, for example, a process for charging all the cells to a fully charged state (i.e., raising the voltage of all the cells to the foreign substance dissolution potential) is assumed. In order to enable such processing, it is desirable to efficiently estimate the full charge capacity of each cell.

It is an object of the present disclosure to efficiently estimate a full charge capacity of each cell when each cell of a bipolar battery is an LFP cell.

(1) A full charge capacity estimation method of the present disclosure is a full charge capacity estimation method for each of a plurality of cells of a bipolar battery. The plurality of cells are stacked in a stack direction. A positive electrode active material of each of the plurality of cells includes lithium iron phosphate. The full charge capacity estimation method includes: during charging of the bipolar battery, for each cell of the plurality of cells, calculating an increase in a charge amount of the cell when a voltage of the cell increases from a first voltage to a second voltage; and estimating a full charge capacity of the cell, using the increase in the charge amount. The first voltage and the second voltage fall within a predetermined voltage range in which the voltage of the cell increases as a positive electrode potential of the cell increases.

According to this method, the full charge capacity of the cell is estimated, using the increase in the charge amount of the cell when the voltage of the cell increases from the first voltage to the second voltage, during charging of the bipolar battery (LFP cell as its cell). The increase in the charge amount of the cell when the voltage of the cell increases from the first voltage to the second voltage is calculated when the voltage of the cell falls within a predetermined voltage range. The predetermined voltage range is a voltage range of a cell in which the voltage of the cell increases as the positive electrode potential of the cell increases, during charging. For the cell including lithium iron phosphate as a positive electrode active material, the increase in the charge amount and the full charge capacity in a predetermined voltage range have a positive linear correlation therebetween. Hence, the second voltage can be set less than the voltage at the time of full charge to determine the increase in the charge amount in the predetermined voltage range, so that the full charge capacity of the cell can be estimated in a relatively short time, without charging the cell to the full state of charge. As a result, the full charge capacity of each cell can be estimated efficiently.

(2) As to the full charge capacity estimation method of (1) as described above, in an aspect, for each cell of the plurality of cells, the predetermined voltage range is a voltage range of the cell in which the voltage of the cell is a predetermined voltage or more. The predetermined voltage is a voltage of the cell when dQ/dV is a second local minimum of a dQ/dV-voltage curve. The dQ/dV is a ratio of the increase in the charge amount, to an increase in the voltage of the cell, and the dQ/dV-voltage curve is a curve representing a relation between the dQ/dV and the voltage of the cell when an SOC of the cell changes from 0% to 100%.

The second local minimum of the dQ/dV-voltage curve is a value of dQ/dV when dQ/dV reaches a local minimum on the dQ/dV-voltage curve for the second time when the SOC increases from 0% to 100%. The voltage value of the cell at which increase in the positive electrode potential starts during charging matches the voltage value corresponding to the second local minimum on the dQ/dV-voltage curve. With this method, the predetermined voltage range can be defined without measuring the positive electrode potential of the cell.

The charging is preferably performed at a rate of 0.1 C or less. The charging is preferably CC charging or CCCV charging.

If charging is performed at a rate of more than 0.1 C, there may be no correlation between the increase in the charge amount and the full charge capacity in a predetermined voltage range. It is therefore preferable to perform charging at a rate of 0.1 C or less. CCCV charging can be performed to ensure that the charging is performed in the predetermined voltage range. The voltage range is a voltage range higher than a voltage corresponding to a second local minimum on the dQ/dV-voltage curve.

A control device of the present disclosure is a control device for a bipolar battery. The bipolar battery includes a plurality of cells that are stacked in a stack direction. A positive electrode active material of each cell of the plurality of cells includes lithium iron phosphate. The control device includes a capacity estimation unit and an equalization control unit. The capacity estimation unit estimates a full charge capacity of each cell by the full charge capacity estimation method according to the above (1) or the above (2). The equalization control unit equalizes respective charge amounts or respective SOCs of the plurality of cells, using the full charge capacity of each cell estimated by the capacity estimation method.

With this configuration, the capacity estimation unit of the control device estimates an increase in the charge amount in a predetermined voltage range. Thus, the full charge capacity can be estimated in a relatively short time, without charging the cell to the full charge state. As a result, the equalization control unit can use this full charge capacity to equalize respective charge amounts or SOCs of the cells. Accordingly, it is possible to efficiently estimate the full charge capacity of each cell in a bipolar LFP battery and equalize respective charge amounts or SOCs of the cells.

The foregoing and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram showing a schematic configuration of a bipolar LFP battery and a capacity inspection system according to the present embodiment.

FIG. 2 is a diagram showing characteristics of a cell at the time of charging.

FIG. 3A is a diagram showing the relationship between the increase in the amount of electric energy stored in the cell and the full charge capacity.

FIG. 3B is a diagram showing the relationship between the increase in the amount of electric energy stored in the cell and the full charge capacity.

FIG. 3C is a diagram showing the relationship between the increase in the amount of electric energy stored in the cell and the full charge capacity.

FIG. 4 is a flowchart showing processing steps of a full charge capacity estimation method performed by the capacity inspection system.

FIG. 5 is a diagram showing a schematic configuration of a control device of a bipolar LFP battery including an equalization circuit.

FIG. 6A is a diagram illustrating characteristics of the LFP battery.

FIG. 6B shows a characteristic of each cell when two LFP cells (cells) different from each other in full charge capacity are charged to a full charge state.

### DESCRIPTION OF THE PREFERRED EMBODIMENTS

Hereinafter, embodiments of the present disclosure will be described in detail with reference to the accompanying drawings. In the drawings, the same or corresponding parts are denoted by the same reference numerals, and the description thereof will not be repeated.

### Embodiment 1

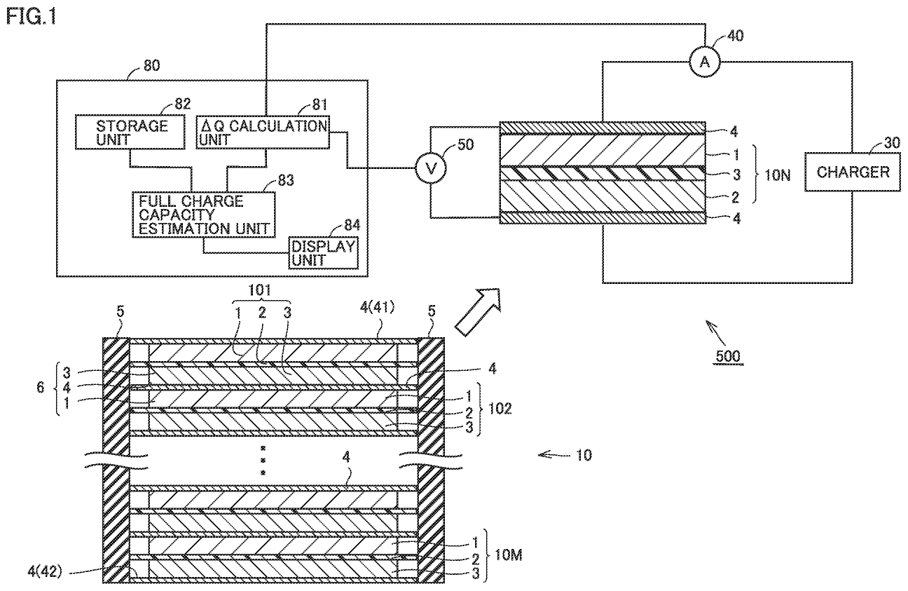

FIG. 1 is a diagram showing a schematic configuration of a bipolar LFP battery (bipolar battery) 10 and a capacity inspection system 500 according to the present embodiment. The bipolar LFP battery 10 includes cells 101, 102 to 10M (M is the number of cells). Each cell is stacked along a frame member (seal member) 5. Each of the cells 101 to 10M includes a positive electrode active material layer (positive electrode) 1, a separator 2, and a negative electrode active material layer (negative electrode) 3. Each of the cells 101 to 10M includes a plurality of bipolar electrodes 6. The adjacent bipolar electrodes 6 are stacked with the separator 2 interposed therebetween. Each bipolar electrode 6 includes a current collector 4, a positive electrode active material layer 1, and a negative electrode active material layer 3. The positive electrode active material layer 1 is formed on one surface (lower surface in FIG. 1) of the current collector 4. The negative electrode active material layer 3 is formed on the other surface (upper surface in FIG. 1) of the current collector 4. The number of stacked cells 101 to 10M is arbitrary, and may be, for example, 20. The current collector 4 arranged at one end (upper end in FIG. 1) in the stack direction also functions as a positive electrode terminal plate 41. The current collector 4 disposed at the other end (lower end in FIG. 1) in the stack direction also functions as a negative electrode terminal plate 42.

In the present embodiment, each of the cells 101 to 10M is a lithium iron phosphate ion battery (LFP battery). The positive electrode active material layer 1 contains lithium iron phosphate (LiFePO₄) as a positive electrode active material. The negative electrode active material layer 3 contains graphite particles a negative electrode active material. Then, by impregnating the separator 2 with the non-aqueous electrolyte solution, the non-aqueous electrolyte solution is sealed. Thus, the bipolar LFP battery 10 is formed.

The capacity inspection system 500 includes a charger 30, a current sensor 40, a voltage sensor 50, and a capacity measurement device 80. The charger 30 charges the bipolar LFP battery 10 by CC charging or CCCV charging. The current sensor 40 detects a charging current [A]. The voltage sensor 50 detects the voltage Vb [V] of each of the cells 10N (N is an integer of 1 to M).

The capacitance measurement device 80 includes a computer and a display. The computer includes a CPU (Central Processing Unit), a memory, and a bus. The capacity measurement device 80 includes, as functional blocks, an increase in a charge amount calculation unit 81, a storage unit 82, a full charge capacity estimating unit 83, and a display unit 84.

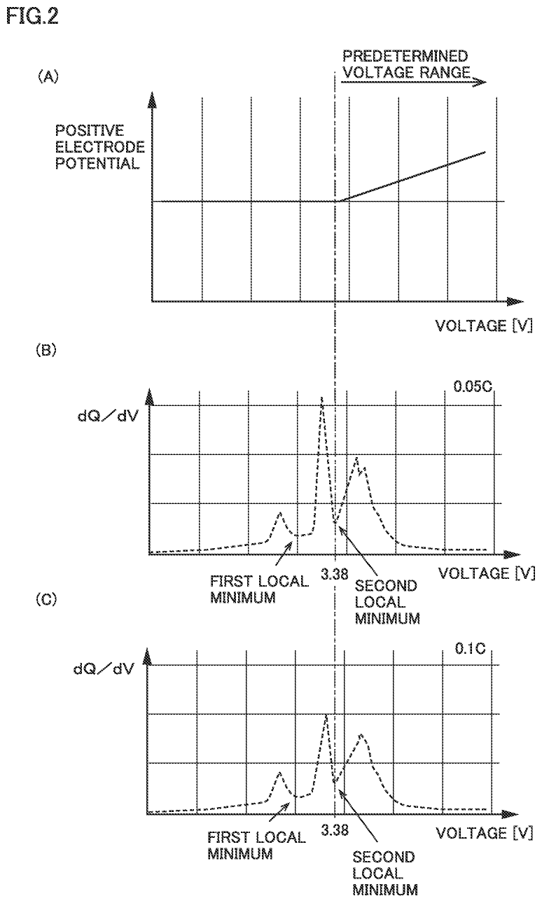

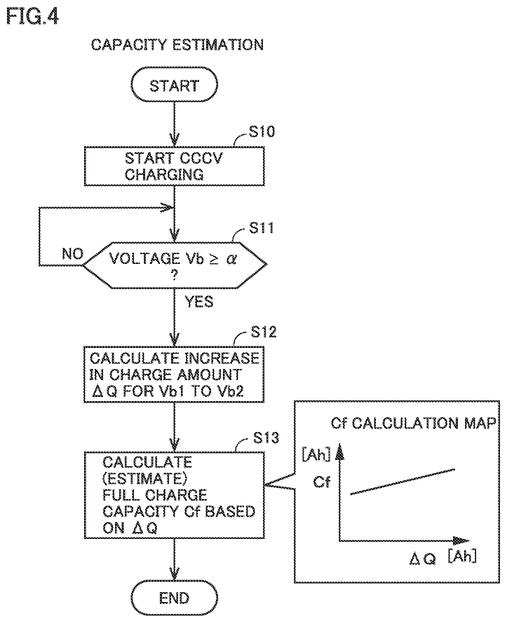

FIG. 2 is a diagram showing characteristics of a cell at the time of charging. In this example, the charging scheme is CCCV charging. The termination voltage (the switching voltage from CC charge to CV charge) is set to 3.75 V. The charge end condition (current at the end of charge) is 0.01 C. FIG. 2A shows the relationship between the voltage of the cell and the positive electrode potential. When the voltage of the cell exceeds 3.38 V, the voltage of the cell rises as the positive electrode potential rises. The middle portion (B) of FIG. 2 shows the relationship between the voltage of the cell and dQ/dV when the cell is charged at a rate of 0.05 C. DQ/dV is a ratio of an increase in the charge amount [Ah] of the cell to an increase in the voltage of the cell. As indicated by the broken line in FIG. 4B, when the voltage of the cell 10N rises (the SOC of the cell increases from 0% to 100%), the first local minimum value and the second local minimum value of the dQ/dV-voltage curve appear. The second local minimum value of the dQ/dV-voltage curve is the value of dQ/dV when dQ/dV becomes the minimum at the second time in the dQ/dV-voltage curve until the SOC increases from 0% to 100%. The voltage corresponding to the second local minimum value is 3.38 V. This voltage is the same as the voltage of the cell 10N when the voltage of the cell 10N begins to rise as the positive electrode potential rises (upper portion (A) of FIG. 2). FIG. 2C shows the relationship between the voltage of the cell and dQ/dV when charging is performed at a rate of 0.1 C. As indicated by the broken line in (C), the voltage corresponding to the second local minimum value of the dQ/dV-voltage curve is 3.38 [V]. This voltage is the same value as the voltage of the cell 10N when the voltage of the cell begins to rise as the positive electrode potential rises (upper portion (A) of FIG. 2).

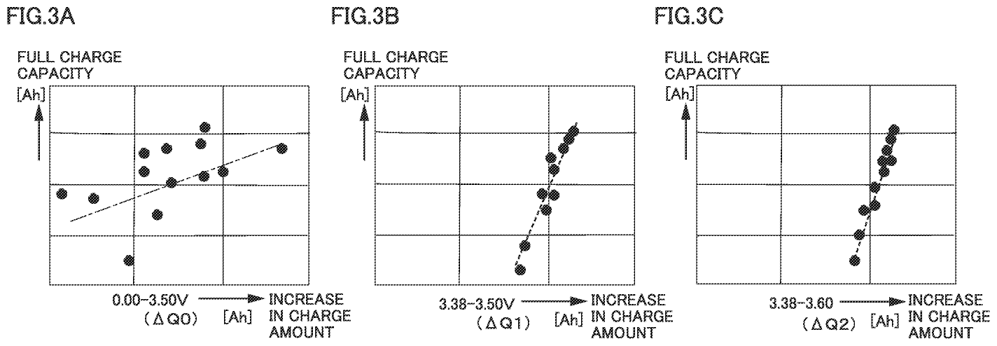

FIG. 3A, FIG. 3B, and FIG. 3C are diagrams showing the relationship between the increase in the amount of electric power stored in the cell and the full charge capacity. An increase in charge amount ΔQ is an increase in the charge amount of the cell when the voltage of the cell increases from the first voltage Vb1 to the second voltage Vb2 by charging. For example, when the charge amount of the cell corresponding to the first voltage Vb1 is Q1[Ah] and the charge amount corresponding to the second voltage Vb2 is Q2[Ah], the increase in charge amount ΔQ is expressed as “ΔQ=Q2−Q1”. In the example of FIG. 3, the termination voltage is set to 3.75 V. The charge end condition is set to 0.01 C. CCCV charging is performed at a rate of 0.05 C.

FIG. 3A is a graph plotting the relationship between ΔQ0 and the full charge capacity of the cell. ΔQ0 is the amount of increase ΔQ in the amount of stored electricity when the state of the cell changes (the cell is charged) from the state in which the SOC of the cell is 0% to the state in which the voltage of the cell is 3.50 [V]. The basis weight of the cell varies due to variations during manufacturing. As a result, as shown in FIG. 3A, the full charge capacity of each cell varies. For each cell, there is no correlation between the full charge capacity and the increase in the charge amount ΔQ(ΔQ0).

FIG. 3B is a graph plotting ΔQ1 and full charge capacity of the cell. ΔQ1 is the increase in the charge amount ΔQ when the voltage of the cell rises from 3.38 V to 3.50 V. The basis weight of the cell varies due to variations during manufacturing. As a result, as shown in FIG. 3B, the full charge capacity of each cell varies. However, for each cell, there is a positive linear correlation between the full charge capacity and the increase in the charge amount ΔQ(ΔQ1).

FIG. 3C is a graph plotting ΔQ2 and full charge capacity of the cell. ΔQ2 is the increase in the charge amount ΔQ in the amount of stored electricity when the voltage of the cell rises from 3.38 V to 3.60 V. The basis weight of the cell varies due to variations during manufacturing. As shown in FIG. 3C, the full charge capacity of each cell varies. However, for each cell, there is a positive linear correlation between the full charge capacity and the increase in the charge amount ΔQ(ΔQ2).

As shown in FIG. 2 and FIGS. 3A to 3C, for the cell 10N of the bipolar LFP battery 10, the increase in charge amount ΔQ in the amount of stored electricity in a predetermined voltage range (a voltage range of 3.38 [V] or more) correlates with the full charge capacity of the cell 10N. This voltage range is the voltage range of the cell in which the voltage of the cell 10N rises as the positive electrode potential rises during charging. The predetermined voltage range is a voltage range higher than the second local minimum value of the dQ/dV-voltage curve. In the present embodiment, the full charge capacity of the cell 10N is estimated by using the correlation between the increase in the charge amount ΔQ in the predetermined voltage range and the full charge capacity.

Referring to FIG. 1, when charger 30 starts CC charging or CCCV charging, increase in charge amount calculation unit (ΔQ calculation unit) 81 of capacity measurement device 80 calculates the increase ΔQ in the charge amount of cell 10N in a predetermined voltage range. The storage unit 82 stores a full charge capacity Cf calculation map. The full charge capacity Cf calculation map is created in advance by experiment or the like based on the correlation between the increase in the charge amount ΔQ and the full charge capacity Cf. The full charge capacity estimation unit 83 calculates the full charge capacity Cf based on the full charge capacity Cf calculation map using the increase in the charge amount ΔQ calculated by the ΔQ calculation unit 81 as a parameter. The calculated full charge capacity Cf is displayed on the display unit 84.

FIG. 4 is a flowchart showing the processing steps of the full charge capacity estimation method performed by the capacity inspection system 500. Hereinafter, the step is abbreviated as “S”. In S10, the charger 30 starts CC charging or CCCV charging of the cell 10N (bipolar LFP battery 10). Subsequently, in S11, the ΔQ calculation unit 81 determines whether or not the voltage Vb of the cell 10N detected by the voltage sensor 50 is equal to or greater than a predetermined value a. The predetermined value a is a voltage corresponding to the second local minimum value of the dQ/dV-voltage curve. This voltage is 3.38 [V] in the case of the cell of FIGS. 2 and 3A to 3C. When the charging progresses and the voltage Vb becomes equal to or greater than the predetermined value a (YES in S11), the process proceeds to S12.

In S12, the ΔQ calculation unit 81 calculates the increase in the charge amount ΔQ based on the detection values of the current sensor 40 and the voltage sensor 50. The increase in the charge amount ΔQ is an increase in the charge amount of the cell 10N when the voltage Vb of the cell 10N rises from the first voltage Vb1 to the second voltage Vb2. The first voltage Vb1 is, for example, 3.38 V. The second voltage Vb2 is, for example, 3.50 V. In S13, the full charge capacity estimation unit 83 calculates (estimates) the full charge capacity Cf of the cell 10N using the full charge capacity Cf calculation map stored in the storage unit 82 based on the increase in the charge amount ΔQ calculated in S12. The processes of S11 to S13 are performed for all the cells 10N included in the bipolar LFP battery 10. Thus, the full charge capacity Cf of all the cells 10N is calculated.

According to this embodiment, after the CC charging or CCCV charging is started, the increase in the charge amount ΔQ is calculated in a predetermined voltage range. This voltage range is a voltage range of the cell 10N in which the voltage Vb of the cell 10N is equal to or greater than a predetermined value a. The predetermined value a is a value of a voltage corresponding to the second local minimum value of the dQ/dV-voltage curve. The increase in the charge amount ΔQ is an increase in the charge amount of the cell 10N when the voltage rises from the first voltage Vb1 to the second voltage Vb2. Each of the first voltage Vb1 and the second voltage Vb2 is within the predetermined voltage range described above. After the calculation of the increase of the charge amount ΔQ, the full charge capacity Cf of the cell 10N is estimated (calculated) based on the full charge capacity Cf calculation map using the increase in the charge amount ΔQ as a parameter. The second voltage Vb2 is lower than the fully charged voltage of the cell 10N. Therefore, according to the embodiment, the full charge capacity Cf can be estimated in a relatively short time by calculating the increase in the charge amount ΔQ without charging the cell 10N until full charge. The increase in the charge amount ΔQ is an increase in the charge amount of the cell 10N in a predetermined voltage range equal to or greater than a voltage (predetermined value a) corresponding to the second local minimum value of the dQ/dV-voltage curve. By estimating the full charge capacity Cf as described above, the full charge capacity Cf of the cell 10N can be efficiently estimated.

### Embodiment 2

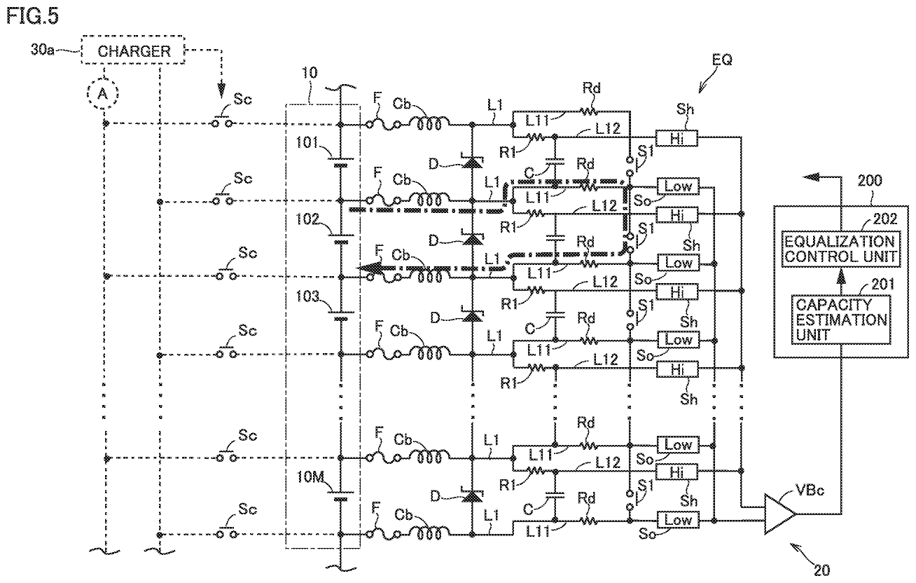

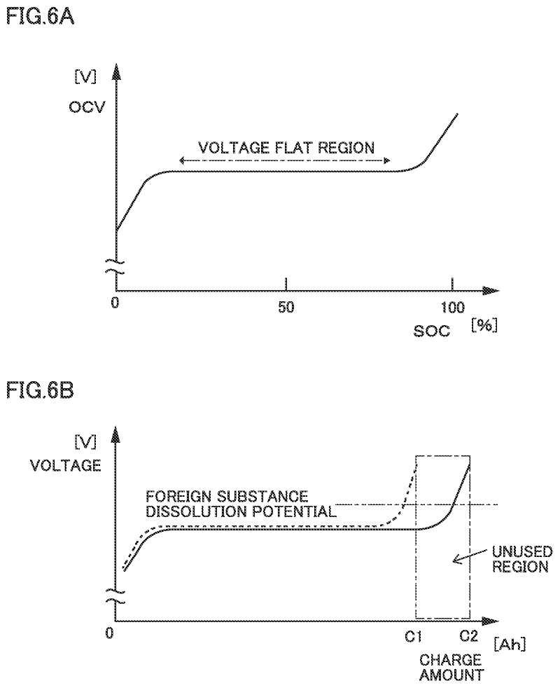

FIG. 5 is a diagram showing a schematic configuration of a control device of a bipolar LFP battery 10 including an equalization circuit. Referring to FIG. 5, voltage detection circuit 20 detects voltages of single cells 101 to 10M via a plurality of voltage detection lines L1, branch lines L11, and branch lines L12. A fuse F and chip beads Cb are provided in the voltage detection line L1 for circuit protection and the like. The plurality of Zener diodes D are provided in parallel with the single cells 101 to 10M, respectively, and are provided to protect the voltage detection circuit 20 from overvoltage.

The voltage detection line L1 branches into a branch line L11 and a branch line L12 on the voltage detection section VBc side from the Zener diode D. The branch line L11 is connected to the voltage detection section VBc via a switch So. The branch line L12 is connected to the voltage detection section VBc via a switch Sh. Each of the switch So and the switch Sh is, for example, a photo MOS (Metal Oxide Semiconductor) relay.

The branch line L12 is provided with a resistor R1. The branch line L12 is connected to the positive electrode of the corresponding single cell. The branch line L11 is connected to the negative electrode of the corresponding single cell. A capacitor (flying capacitor) C is provided between the branch lines L11 and L12. Thus, the voltage detection section VBc sequentially turns on the switches Sh and So corresponding to the single cells 101 to 10M for each of the single cells 101 to 10M, thereby detecting the voltage Vb of each of the cells 101 to 10M by using the voltage detection circuit 20 by the flying capacitor method.

The equalization circuit EQ includes a plurality of discharge resistors Rd and a plurality of switches S1. Each discharge resistor Rd is provided in a corresponding branch line L11. Each of the switches S1 is provided to conduct (close)/close (open) between two adjacent branch lines L11. Each switch S1 is switched between ON (closed) and OFF (open) by receiving a control signal from the BT-ECU 220. When the switch S1 is turned on (closed), the current discharged from the corresponding cell 102 is consumed by the discharge resistor Rd, as indicated by an arrow of a dot-and-dash line. Thereby, the amount of electric power stored in the corresponding cell 102 decreases (decreases).

The control device 200 is a computer and includes a CPU, a memory, and a bus. The capacity estimating unit 201 of the control device 200 has the same function as the capacity measurement device 80. When the charger 30a performs CC charging or CCCV charging, the capacity estimation unit 201 calculates (estimates) the full charge capacity Cf of the cells 101 to 10M using the same full charge capacity estimation method as in the first embodiment.

The equalization control unit 202 sets the smallest full charge capacity Cf among the full charge capacities Cf of the cells 101 to 10M estimated by the capacity estimation unit 201 as the reference capacity Cfm. When the charging of the bipolar LFP battery 10 is finished, the equalization control unit 202 sequentially turns on the switch S1 corresponding to the cell having the full charge capacity Cf larger than the reference capacity Cfm to discharge the cells. The discharge amount of each cell may be set in advance by experiment or the like so as to be proportional to the deviation between the full charge capacity Cf and the reference capacity Cfm of the cell. By discharging the cells as described above, the charge amounts [Ah] of the cells 101 to 10M can be equalized.

The equalization control unit 202 may control the equalization circuit EQ to equalize the SOC of the cell 101. At the end of charging of the bipolar LFP battery 10, when the SOC of the cells 101 to 10M is non-uniform, the value of the SOC becomes larger as the full charge capacity Cf becomes smaller. The equalization control unit 202 sets the largest full charge capacity Cf among the full charge capacities Cf of the cells 101 to 10M estimated by the capacity estimation unit 201 as the reference capacity Cfx. When the charging of the bipolar LFP battery 10 is finished, the equalization control unit 202 sequentially turns on the switch S1 corresponding to the cell having the full charge capacity Cf smaller than the reference capacity Cfx to discharge the cells. The discharge amount of each cell may be set in advance by experiment or the like so as to be proportional to the deviation between the full charge capacity Cf and the reference capacity Cfx of the cell. By discharging the cells as described above, the SOCs of the cells 101 to 10M can be equalized.

According to this embodiment, the capacity estimating unit 201 of the control device 200 calculates the increase in the charge amount ΔQ in the amount of stored electricity in the predetermined voltage range, thereby estimating the full charge capacity Cf in a relatively short time without charging the cell 10N until full charge. The equalization control unit 202 can equalize the charge amount or SOC of the cell 102 using the full charge capacity Cf. Therefore, the full charge capacity Cf of the cell 10N (the LFP battery 10) of the bipolar battery can be efficiently estimated, and the amount of charge or SOC of the cell 10N can be equalized.

As illustrated by a broken line in FIG. 5, a plurality of switches Sc may be provided in the equalization circuit EQ so that the charging power (charging current) from the charger 30a can be supplied to each of the cells 101 to 10M. According to this configuration, by turning on (closing) the switch Sc corresponding to each of the cells 101 to 10M, charging (CC charging, CCCV charging) can be performed for each of the cells 101 to 10M. After the charging of the bipolar LFP battery 10 is finished, the equalization control unit 202 may control the charger 30a and the switch Sc to perform additional charging for the cell having the large full charge capacity Cf estimated by the capacity measurement device 80 or the capacity estimating unit 201. Thereby, the voltage of the cell having the large full charge capacity Cf is increased to be equal to or higher than the foreign substance dissolution potential, whereby the foreign substance can be dissolved.

Although the present disclosure has been described and illustrated in detail, it is clearly understood that the same is by way of illustration and example only and is not to be taken by way of limitation, the scope of the present disclosure being interpreted by the terms of the appended claims.

What is claimed is:

1. A full charge capacity estimation method for each of a plurality of cells of a bipolar battery, the plurality of cells being stacked in a stack direction, a positive electrode active material of each of the plurality of cells including lithium iron phosphate, the full charge capacity estimation method comprising:
during charging of the bipolar battery, for each cell of the plurality of cells,
calculating an increase in a charge amount of the cell when a voltage of the cell increases from a first voltage to a second voltage; and
estimating a full charge capacity of the cell, using the increase in the charge amount, wherein
the first voltage and the second voltage fall within a predetermined voltage range in which the voltage of the cell increases as a positive electrode potential of the cell increases.

2. The full charge capacity estimation method according to claim 1, wherein
for each cell of the plurality of cells,
the predetermined voltage range is a voltage range of the cell in which the voltage of the cell is a predetermined voltage or more, and the predetermined voltage is a voltage of the cell when dQ/dV is a second local minimum of a dQ/dV-voltage curve, where
the dQ/dV is a ratio of the increase in the charge amount, to an increase in the voltage of the cell, and
the dQ/dV-voltage curve is a curve representing a relation between the dQ/dV and the voltage of the cell when an SOC of the cell changes from 0% to 100%.

3. The full charge capacity estimation method according to claim 2, wherein the charging is performed at a rate of 0.1 C or less.

4. The full charge capacity estimation method according to claim 1, wherein the charging is CC charging or CCCV charging.

5. A control device for a bipolar battery, the bipolar battery including a plurality of cells that are stacked in a stack direction, a positive electrode active material of each cell of the plurality of cells including lithium iron phosphate, the control device comprising:
a capacity estimation unit that estimates a full charge capacity of each cell by the full charge capacity estimation method according to claim 1; and
an equalization control unit that equalizes respective charge amounts or respective SOCs of the plurality of cells, using the full charge capacity of each cell estimated by the capacity estimation method.
